(19) United States
(12) Patent Application Publication
(10) Pub. No.: US 2026/0354189 A1
(43) Pub. Date: Nov. 5, 2026

(54) SEMICONDUCTOR PACKAGE COMPRISING DUMMY DIE BONDED TO DIFFERENT BONDING LAYERS

(71) Applicant: Taiwan Semiconductor Manufacturing Co., Ltd., Hsinchu (TW)

(72) Inventors: Kuo-Chiang Ting, Hsinchu (TW); Sung-Feng Yeh, Taipei City (TW); Ta Hao Sung, Hsinchu (TW); Shu-Yan Jhu, Hsinchu (TW)

(73) Assignee: Taiwan Semiconductor Manufacturing Co., Ltd., (omitted)

(21) Appl. No.: 19/739,112

(22) Filed: Jul. 13, 2026

Related U.S. Application Data
(62) Division of application No. 18/341,897, filed on Jun. 27, 2023.

(51) Int. Cl. H10W 40/70; H10W 74/01; H10W 74/10; H10W 90/00; H10W 72/90; H10W 80/00

(52) U.S. Cl. CPC H10W 40/70; H10W 74/01; H10W 74/111; H10W 90/00; H10W 72/9445; H10W 80/312; H10W 80/327; H10W 90/792

(57) ABSTRACT

A semiconductor package with a dummy die having two layers with different thermal conductivities and the method of forming the same are provided. The semiconductor package may include a first semiconductor die, a first bonding layer on the first semiconductor die, a second semiconductor die bonded to the first bonding layer, and a first dummy die bonded to the first bonding layer. The first dummy die may include a substrate, a material layer between the substrate and the first bonding layer, and a second bonding layer between the material layer and the first bonding layer. The material layer may include a first material with a first thermal conductivity and the second bonding layer may include a second material with a second thermal conductivity different from the first thermal conductivity.

### PRIORITY CLAIM AND CROSS-REFERENCE

This application is a divisional of U.S. Patent Application No. 18/341,897, filed on Jun. 27, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a trend for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5A, 5B, 5C, 6, 7, 8, 9, 10. and 11 illustrate cross-sectional and top-down views of intermediate steps during the manufacturing of a semiconductor package, in accordance with some embodiments.

FIGS. 12, 13A, 13B, 13C, 13D, 13E, 14A, 14B, 15A, and 15B illustrate cross-sectional and top-down views of various semiconductor packages, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package and the method of forming the same are provided. In accordance with some embodiments, the semiconductor package may comprise one or more dummy dies bonded to a semiconductor die. The one or more dummy dies may be bonded to the semiconductor by bonding a first dielectric layer in each dummy die to a second dielectric layer on the semiconductor die. The semiconductor die may comprise heat generating electrical devices. Each dummy die may comprise a material layer in contact with the first dielectric layer and first dummy pads extending through the first dielectric layer. Second dummy pads may be disposed in the second dielectric layer and in contact with the first dummy pads. The material layer and first dummy pads in each dummy die, as well as the second dummy pads in the second dielectric layer may transfer heat generated by the electrical devices during operation away from the semiconductor package, thereby leading to higher efficiency and better long-term reliability of the semiconductor package.

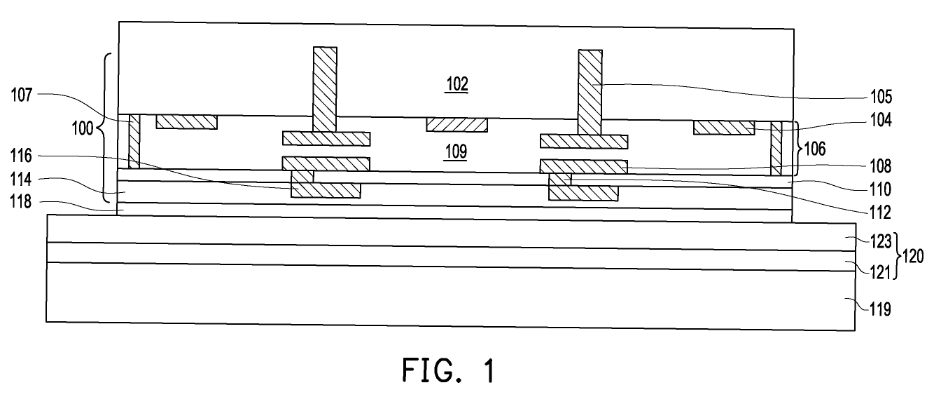

FIGS. 1 -11 are cross-sectional and top-down views of intermediate steps during the manufacturing of a semiconductor package including dummy dies with heat dissipation layers, in accordance with some embodiments.

Referring to FIG. 1, a bottom semiconductor die 100 is attached to a first carrier 119. The bottom semiconductor die 100 may be a bare semiconductor die (e.g., unpackaged semiconductor die) that is formed as part of a larger wafer. For example, the bottom semiconductor die 100 may be a logic die (e.g., application processor (AP), central processing unit (CPU), microcontroller, etc.), a memory die (e.g., dynamic random access memory (DRAM) die, hybrid memory cube (HBC), a static random access memory (SRAM) die, a wide input/output (wide IO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. The bottom semiconductor die 100 may be a package comprising one or more bare semiconductor dies.

The bottom semiconductor die 100 may be processed according to applicable manufacturing processes to form integrated circuits in the bottom semiconductor die 100. The bottom semiconductor die 100 may be formed as part of a larger wafer with other semiconductor dies and subsequently singulated from the wafer. The bottom semiconductor die 100 may include a substrate 102, such as silicon, doped or undoped, or an active layer of a semiconductor-on-insulator (SOI) substrate. The substrate 102 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Electrical devices 104 (i.e., active and/or passive devices), such as transistors, diodes, capacitors, resistors, and the like, may be formed in and/or on the substrate 102. The electrical devices 104 may be interconnected by an interconnect structure 106 comprising metallization patterns 108 in one or more dielectric layers 109 on the substrate 102. The interconnect structure 106 electrically connect the electrical devices 104 on the substrate 102 to form one or more integrated circuits. The metallization patterns 108 may comprise conductive material such as, copper, aluminum, or the like. The one or more dielectric layers 109 may comprise low-k dielectric materials, such as silicon oxide or the like. Seal ring 107 may be formed in the interconnect structure 106 and may extend through the one or more dielectric layers 109 of the interconnect structure 106. The seal ring 107 may encircle the electrical devices 104 in a top-down view. In some embodiments, the seal ring 107 is formed of a same material and the metallization patterns 108. The electrical devices 104 may generate relatively high levels of heat during operation, thereby creating thermal hotspots.

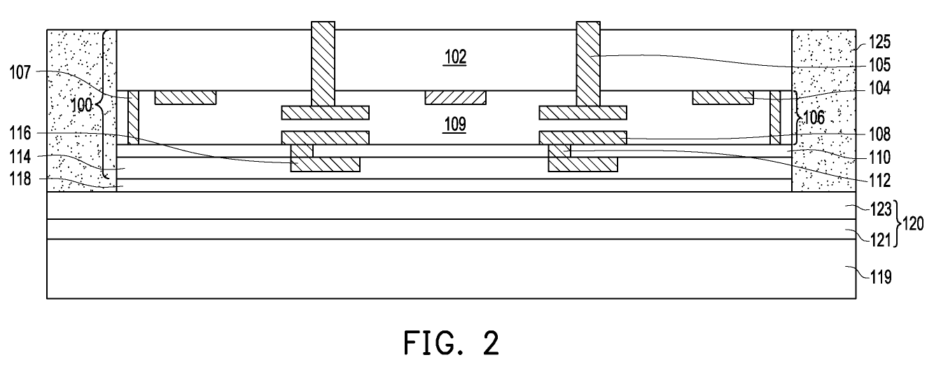

The bottom semiconductor die 100 may further include through vias 105, which may be electrically connected to the metallization patterns 108 in the interconnect structure 106. The through vias 105 may comprise a conductive material such as, copper, aluminum, or the like, and may extend from the interconnect structure 106 into the substrate 102. One or more insulating barrier layers (not shown) may be formed around at least portions of the through vias 105 in the substrates 102. In subsequent processing steps (e.g., see FIG. 2), the substrate 102 may be thinned to expose the through vias 105. After being exposed, the through vias 105 may provide electrical connection from a back side of the substrate 102 to a front side of the substrate 102. In some embodiments, the back side of the substrate 102 may refer to a side of the substrate 102 opposite to the electrical devices 104 and the interconnect structure 106 while the front side of the substrate 102 may refer to a side of the substrate 102 on which the electrical devices 104 and the interconnect structure 106 are disposed.

The bottom semiconductor die 100 may further comprise one or more passivation layers 110 on the interconnect structure 106 and conductive vias 112 extending through the one or more passivation layers 110. The conductive vias 112 may be in electrical connection with the metallization patterns 108. The one or more passivation layers 110 may comprise dielectric materials, such as silicon nitride, silicon oxycarbide, or the like. The conductive vias 112 may comprise a conductive material such as, copper, aluminum, or the like. A dielectric layer 114 is disposed on the one or more passivation layers 110 and contact pads 116 are embedded in the dielectric layer 114. The contact pads 116 may be in electrical connection with the conductive vias 112. In subsequent processing steps, openings may be formed in the dielectric layer 114 to expose the contact pads 116 (shown in FIG. 8). After being exposed, the contact pads 116 provide electrical connection to the electrical devices 104 and the interconnect structure 106. The dielectric layer 114 may comprise a dielectric material, such as silicon oxide, silicon nitride, or the like. The contact pads 116 may comprise a conductive material such as, copper, aluminum, or the like. A dielectric layer 118 is disposed on the dielectric layer 114. The dielectric layer 118 may comprise a dielectric material, such as silicon oxide, silicon oxynitride, or the like.

The first carrier 119 may be a semiconductor carrier, a glass carrier, a ceramic carrier, or the like. The first carrier 119 may be a wafer. FIG. 1 illustrates one bottom semiconductor die 100 bonded to the first carrier 119 as an example, two or more bottom semiconductor dies 100 may be bonded to the first carrier 119 and processed together during the subsequent manufacturing steps until being singulated into individual semiconductor packages. A bonding layer 120 may be disposed on the first carrier 119. In some embodiments, the bonding layer 120 comprises a first bonding layer 121 on the first carrier 119 and a second bonding layer 123 on the first bonding layer 121. The first bonding layer 121 may comprise a dielectric material, such as silicon oxynitride or the like and the second bonding layer 123 may comprise a dielectric material, such as silicon oxide or the like.

The bottom semiconductor die 100 may be attached to the first carrier 119 by bonding the dielectric layer 118 and the bonding layer 120. The bonding process may include a pre-bonding and an annealing. During the pre-bonding, a small pressing force may be applied to press the bottom semiconductor die 100 against the bonding layer 120. The pre-bonding may be performed at a low temperature, such as room temperature, and after the pre-bonding, the dielectric layer 118 is bonded to the bonding layer 120. The bonding strength may be then improved in a subsequent annealing step, in which the dielectric layer 118 and the bonding layer 120 are annealed. After the annealing, dielectric-to-dielectric bond, such as covalent bond, may be formed, which bonds the dielectric layer 118 to the bonding layer 120.

In FIG. 2, a bottom encapsulant 125 is formed over the first carrier 119, and the substrate 102 and the bottom encapsulant 125 are thinned to expose the through vias 105. The bottom encapsulant 125 may extend along sidewalls of the bottom semiconductor die 100 and encircle the bottom semiconductor die 100 in a top-down view. In some embodiments, the bottom encapsulant 125 may comprise silicon oxide, silicon nitride, silicon carbide, silicon carbonitride, silicon oxynitride, silicon oxycarbonitride, un-doped silicate glass (USG), or the like, and may be formed using a suitable deposition process such as chemical vapor deposition (CVD), physical vapor deposition (PVD), atomic layer deposition (ALD), or the like. In some embodiments, the bottom encapsulant 125 may comprise a molding compound, an epoxy, a resin, or the like and may be formed by applying compression molding, transfer molding, or the like before being cured.

The substrate 102 is thinned to expose the through vias 105. Portions of the bottom encapsulant 125 may also be removed by the thinning process. The thinning process may be, a chemical-mechanical polish (CMP) process, a grinding process, an etch-back process, the like, or a combination thereof. In some embodiments, the substrate 102 is further recessed to expose sidewalls of the through vias 105. The recessing process may be a selective etching process, such as a dry etch, a wet etch, or combinations thereof. After the recessing process, the through vias 105 may protrude from the back side of the substrate 102.

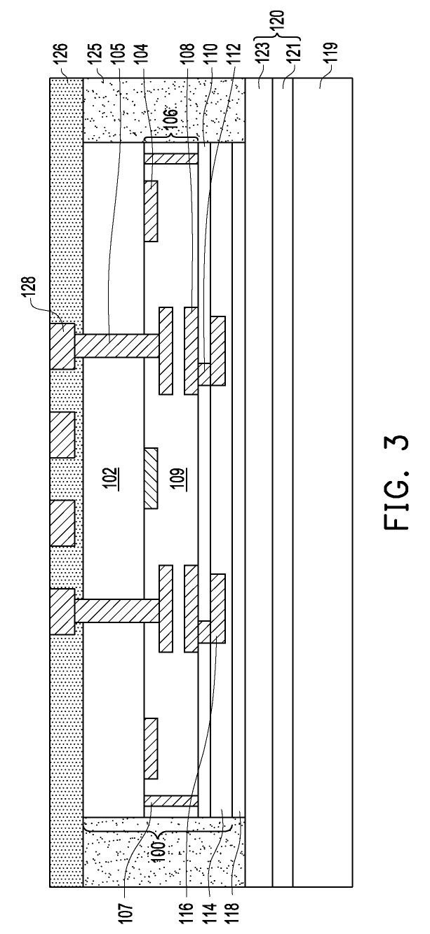

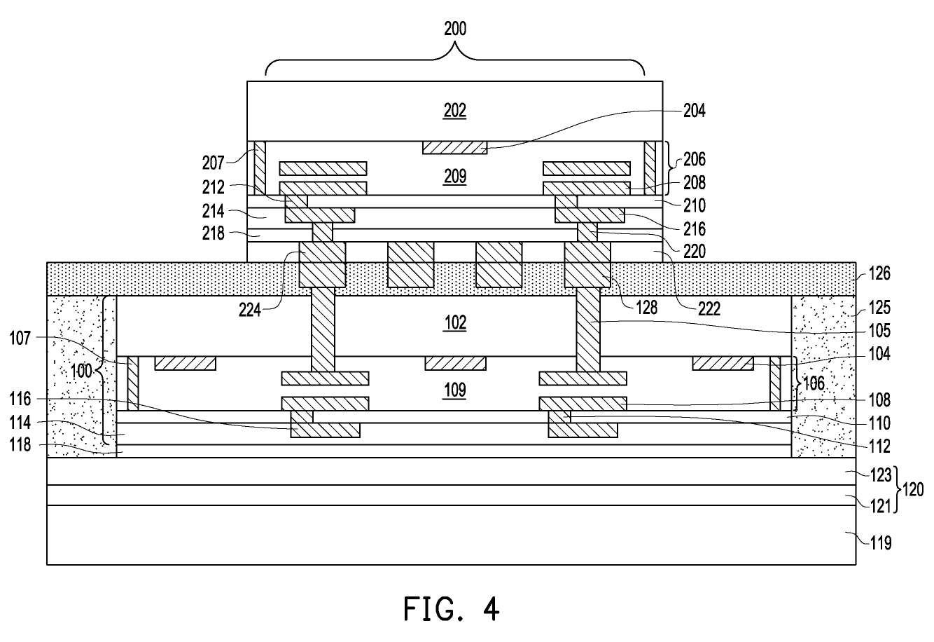

In FIG. 3, a bonding layer 126 is formed over the substrate 102, the bottom encapsulant 125, and the through vias 105, and bonding pads 128 are formed in the bonding layer 126. The bonding layer 126 may be used to bond to another device in a subsequent process, such as bonding to a top semiconductor die 200 as shown in FIG. 4. The bonding layer 126 may comprise silicon oxide, silicon nitride, silicon carbide, silicon carbonitride, silicon oxynitride, silicon oxycarbide, silicon oxycarbonitride, USG, or the like, and may be formed using a suitable deposition process such as CVD, PVD, ALD, or the like.

The bonding pads 128 are formed in the bonding layer 126 by techniques such as a damascene process, dual damascene process, or the like. The bonding pads 128 may be embedded in the bonding layer 126, wherein top surfaces of the bonding pads 128 are exposed, and sidewalls as well as bottom surfaces of the bonding pads 128 are in contact with the bonding layer 126. Some of the bonding pads 128 may be electrically connected to the through vias 105 and may be electrically connected to the electrical devices 104 of the bottom semiconductor die 100 by the through vias 105. As a result, the bonding pads 128 may provide external devices access to the electrical devices 104. Some of the bonding pads 128 may be dummy bonding pads and may be electrically isolated from the circuitry of the bottom semiconductor die 100. As an example of forming the bonding pads 128, openings may be formed in the bonding layer 126 and may expose the underlying through vias 105. Forming the openings may include forming a patterned mask, such as a photoresist or one or more layers of dielectric material over the bonding layer 126, and performing a selective etching process, such as wet or dry etching, to remove the exposed portions of the bonding layer 126 and expose top surfaces of the through vias 105. The patterned mask may be removed after the etching process. The bonding pads 128 may be formed in the openings. The bonding pads 128 may comprise a conductive material, such as copper, aluminum, or the like, and formed by an electro-chemical plating process, an electroless plating process, CVD, ALD, PVD, the like, or a combination thereof. A planarization process, such as CMP, may be performed to remove the excess conductive material. As a result, top surfaces of the bonding layer 126 and the bonding pads 128 may be substantially co-planar or level.

In FIG. 4, a top semiconductor die 200 is bonded to the bonding layer 126 and the bonding pads 128 on the bottom semiconductor die 100. One top semiconductor die 200 is illustrated as being bonded to the bottom semiconductor die 100 in FIG. 4 as an example, in some embodiments, multiple top semiconductor dies 200 may be bonded to the bottom semiconductor die 100. The top semiconductor die 200 may be a bare semiconductor die (e.g., unpackaged semiconductor die) that is formed as part of a larger wafer or a package comprising one or more bare semiconductor dies, similar to the bottom semiconductor die 100. The top semiconductor die 200 may be processed according to applicable manufacturing processes to form integrated circuits in the top semiconductor die 200. The materials and manufacturing processes of the features in the top semiconductor die 200 may be found by referring to the like features in the bottom semiconductor die 100, wherein the like features in the bottom semiconductor die 100 having reference numerals starting with number “1” corresponding to the features in the top semiconductor die 200 having reference numerals starting with number “2.”

The top semiconductor die 200 includes a substrate 202 and electrical devices 204 (i.e., active and/or passive devices), such as transistors, diodes, capacitors, resistors, and the like, formed in and/or on the substrate 202. An interconnect structure 206 is on the substrate 202. The interconnect structure 206 may include metallization patterns 208 in one or more dielectric layers 209, and the metallization patterns 208 electrically connect the electrical devices 204 on the substrate 202 to form one or more integrated circuits. Seal ring 207 may extend through the one or more dielectric layers 209 of the interconnect structure 206 and encircle the electrical devices 204 in the top-down view. In some embodiments, a back side of the substrate 202 may refer to a side of the substrate 202 opposite to the electrical devices 204 and the interconnect structure 206 while the front side of the substrate 202 may refer to a side of the substrate 202 on which the electrical devices 204 and the interconnect structure 206 are disposed.

The top semiconductor die 200 may further include one or more passivation layers 210 on the interconnect structure 206 and conductive vias 212 extending through the one or more passivation layers 210. The conductive vias 212 may be in electrical connection with the metallization patterns 108. A dielectric layer 214 is on the one or more passivation layers 210 and contact pads 216 are embedded in the dielectric layer 214. The contact pads 216 may be in electrical connection with the conductive vias 212. A dielectric layer 218 is on the dielectric layer 214, and conductive vias 220 extend through the dielectric layer 218 and into the dielectric layer 214. The conductive vias 212 may be in electrical connection with the contact pads 216. The conductive vias 220 may comprise a same or similar material as the conductive vias 212. A bonding layer 222 is on the dielectric layer 218 and bonding pads 224 extend through the bonding layer 222. Some of the bonding pads 224 may be are electrically connected to the conductive vias 220 and may be electrically connected to the electrical devices 204 of the top semiconductor die 200. As a result, the bonding pads 224 may provide external devices access to the electrical devices 204. Some of the bonding pads 224 may be dummy bonding pads and may be electrically isolated from the circuitry of the top semiconductor die 200. Bottom surfaces of the bonding layer 222 and the bonding pads 224 may be substantially co-planar or level. The bonding layer 222 may be formed of a same or similar material and by a same or similar method as the bonding layer 126. The bonding pads 224 may be formed of a same or similar material and by a same or similar method as the bonding pads 128. The material of the bonding layer 126 and the bonding layer 222 may be selected so that dielectric-to-dielectric bonding may be formed between the bonding layer 126 and the bonding layer 222, and the material of the bonding pads 128 and the bonding pads 224 may be selected so that metal-to-metal bonding may be formed between the bonding pads 128 and the bonding pads 224, as discussed below.

The top semiconductor die 200 may be bonded to the bonding layer 126 and the bonding pads 128 on the bottom semiconductor die 100 using a bonding process, wherein the bonding layer 222 of the top semiconductor die 200 may be directly bonded to the bonding layer 126 on the bottom semiconductor die 100, and the bonding pads 224 of the top semiconductor die 200 may be directly bonded to the bonding pads 128 on the bottom semiconductor die 100. The top semiconductor die 200 may be disposed face down such that a front side of the substrate 202 faces the back side of the substrate 102, which may be referred to as a front-to-back package configuration. In some embodiments, the bond between the bonding layer 222 and the bonding layer 126 is an dielectric-to- dielectric bond, or the like, and the bond between the bonding pads 224 and the bonding pads 128 is a metal-to-metal bond, thereby providing electrical connection between the bottom semiconductor die 100 and the top semiconductor die 200.

As an example, the bonding process may start with a surface treatment to the bonding layer 126 and the bonding layer 222. The surface treatment may include a plasma treatment in a vacuum environment. The surface treatment may further include a cleaning process, such as a rinse with deionized water, or the like. The bonding process may then proceed to aligning the bonding pads 224 to the bonding pads 128, so that the bonding pads 224 may overlap with the corresponding bonding pads 128. Next, the pre-bonding may be performed, during which the top semiconductor die 200 is put in contact with the bonding layer 126 and the bonding pads 128 at room temperature (e.g., between about 21° C. and about 25° C.). During the pre-bonding, a small pressing force may be applied to press the top semiconductor die 200 against the top semiconductor die 200. The bonding process may continue with performing an annealing, so that the metal in the bonding pads 224 and the metal in the bonding pads 128 inter-diffuse across the interfaces between the bonding pads 224 and the bonding pads 128, which forms the metal-to-metal bond, and the materials of bonding layer 126 and the bonding layer 222 react to form dielectric-to-dielectric bond.

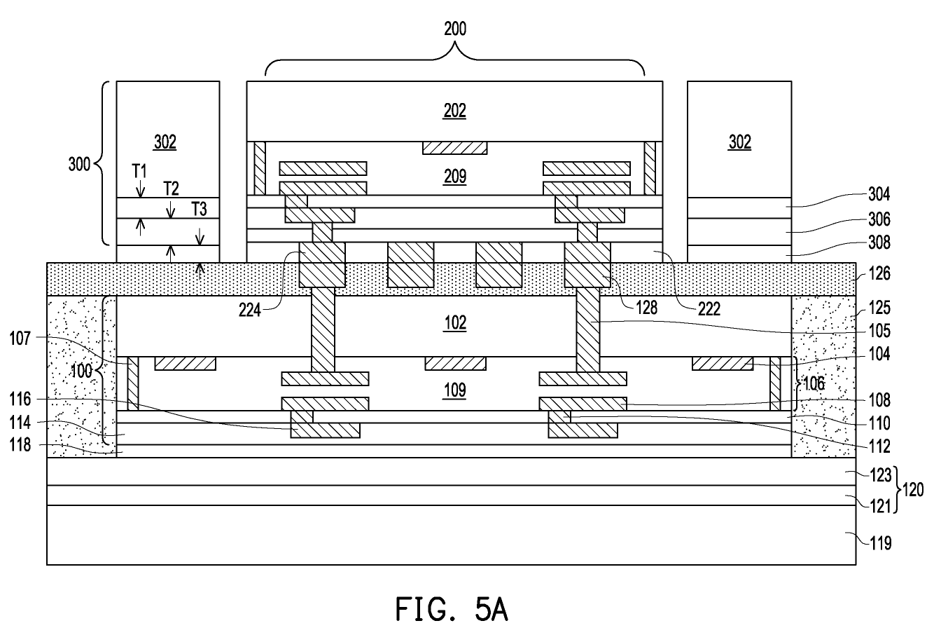

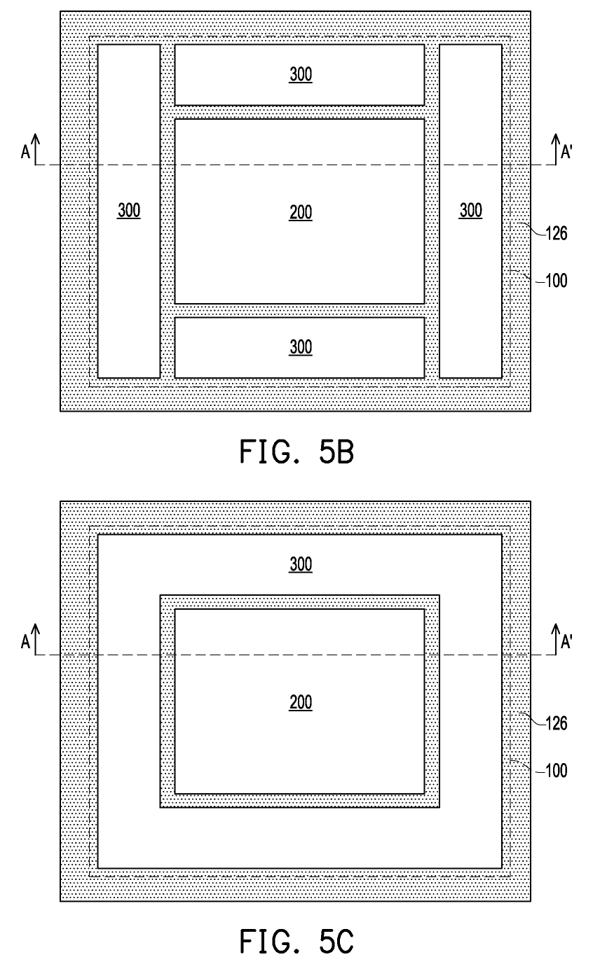

In FIG. 5A, one or more dummy dies 300 are bonded to the bonding layer 126. The dummy dies 300 may be pathways for transferring the heat generated by the electrical devices 104 during operation away from the semiconductor package, which may mitigate the thermal hotspots in the bottom semiconductor die 100, thereby leading to higher efficiency and better long-term reliability of the semiconductor package. Each dummy die 300 may comprise a substrate 302, a dielectric layer 304 on the substrate 302, and a material layer 306 on the dielectric layer 304. The dielectric layer 304 may be an adhesion layer that adheres the material layer 306 to the substrate 302. In some embodiments, the dielectric layer 304 is omitted as described in greater detail below. The material layer 306 may have a high thermal conductivity and a high Young’s Modulus (e.g., high stiffness), which both lead to a higher heat transfer efficiency of the dummy die 300, as described in greater detail below. Each dummy die 300 may further comprise a dielectric layer 308 on the material layer 306. The dielectric layer 308 may be a bonding layer that bonds the dummy die 300 to the bonding layer 126. During the bonding process, the dielectric layer 308 of each dummy die 300 may be bonded to the bonding layer 126 by dielectric-to-dielectric bonding, which is similar to the bonding between the bonding layer 222 and the bonding layer 126 as described with respect to FIG. 4. After the bonding process, a side of the substrates 302 facing the bonding layer 126 may be referred to as a front side of the substrate 302, and a side of the substrates 302 opposite the front side of the substrates 302 may be referred to as a back side of the substrates 302.

The substrate 302 may comprise a same or similar material as the substrate 102. The dielectric layer 304 may comprise silicon oxide, silicon oxynitride, silicon oxycarbide or the like. The dielectric layer 304 may have a first thickness T1 in a range from about 45 nm to about 55 nm, such as about 50 nm. The dielectric layer 304 may have a first thermal conductivity and a first Young’s Modulus. The material layer 306 may comprise a material with a high thermal conductivity, such as greater than 1.5 W/m·K, and/or a high Young’s Modulus, such as greater than 80 GPa. A high thermal conductivity of the material layer 306 may lead to a higher heat transfer efficiency of the dummy die 300. A high Young’s Modulus of the material layer 306 may lead to reduced thicknesses of the dielectric layer 304 and dielectric layer 308 while maintaining similar level of warpage control of the dummy die 300, which may contribute to the effectiveness of the bonding between the dummy die 300 and the bonding layer 126. Reducing the thicknesses of the dielectric layer 304 and dielectric layer 308 may also lead to a higher heat transfer efficiency of the dummy die 300, as described in greater detail below. The material layer 306 may have a second thermal conductivity and a second Young’s Modulus. The material layer 306 may comprise amorphous silicon, silicon nitride, silicon carbide, or the like. The material layer 306 may have a second thickness T2 in a range from about 400 nm to about 500 nm, such as about 450 nm. The dielectric layer 308 may comprise silicon oxide, silicon oxynitride, silicon oxycarbide or the like. The dielectric layer 308 may have a third thickness T3 in a range from about 45 nm to about 55 nm, such as about 50 nm. The dielectric layer 308 may have a third thermal conductivity and a third Young’s Modulus. The second thickness T2 may be larger than the first thickness T1 and the third thickness T3. The second thermal conductivity may be larger than the first thermal conductivity and the third thermal conductivity. The second Young’s Modulus may be larger than the first Young’s Modulus and the third Young’s Modulus.

The substrate 302 may have a fourth thermal conductivity, larger than the first thermal conductivity of the dielectric layer 304 and the third thermal conductivity of the dielectric layer 308. When the thicknesses of the dielectric layer 304 and dielectric layer 308 are reduced and the thickness of the dummy die 300 remains the same, the thickness of the substrate 302 may be increased. Therefore, reducing the thicknesses of the dielectric layer 304 and dielectric layer 308 may increase the heat transfer efficiency of the dummy die 300.

FIGS. 5B and 5C show top-down views of the structure shown in FIG. 5A, in accordance with some embodiments. The cross-sectional view shown in FIG. 5A may be obtained from the reference cross-section A-A’ in the top-down view shown in FIGS. 5B and 5C, wherein like reference numerals refer to like features. The bottom semiconductor die 100 that is covered by the bonding layer 126 is shown in dashed lines for illustrative purposes. FIG. 5B illustrates an example in which four dummy die 300 are disposed on the bonding layer 126. Each dummy die 300 has a rectangular shape and extends along a side of the top semiconductor die 200 in the top-down view. FIG. 5C illustrates an example in which one dummy die 300 with a shape of a frame is disposed on the bonding layer 126. The dummy die 300 may encircle the top semiconductor die 200 in the top-down view. Other shapes, sizes, numbers, and arrangements of the dummy dies 300 are also contemplated.

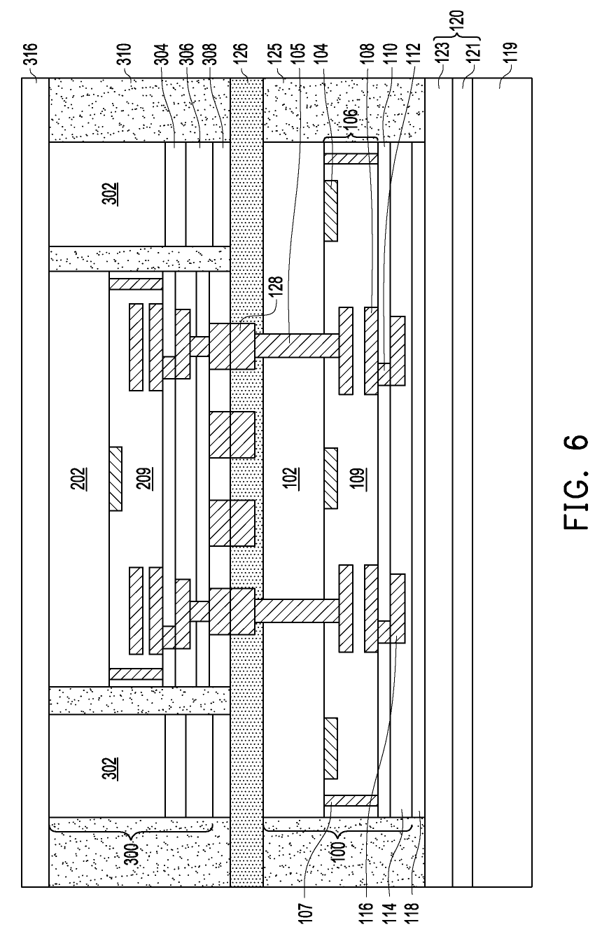

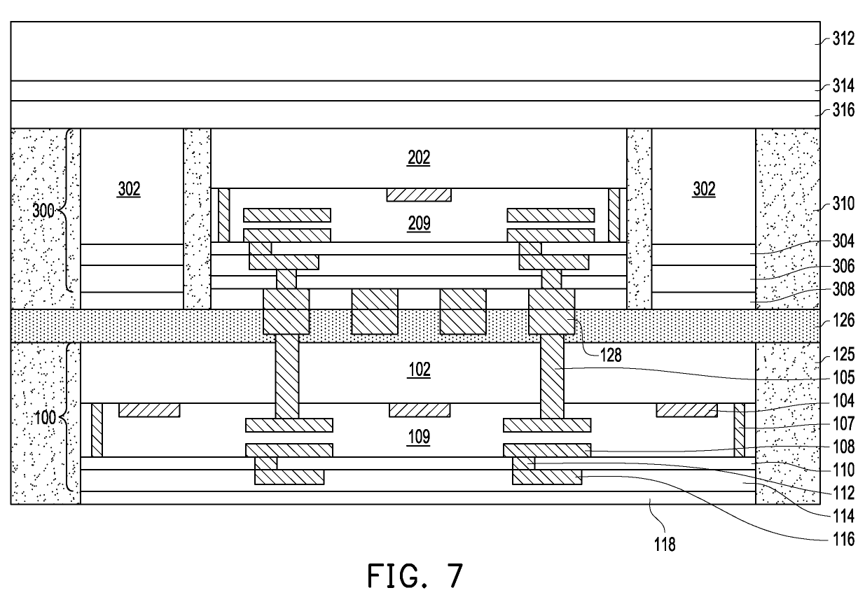

In FIG. 6, a top encapsulant 310 is formed over the remaining portions of the bonding layer 126, and a dielectric layer 316 is formed on the top encapsulant 310, the top semiconductor die 200, and the dummy dies 300. The top encapsulant 310 may extend along sidewalls of the top semiconductor die 200 and the dummy dies 300, and encircle the top semiconductor die 200 and the dummy dies 300 in the top-down view. The top encapsulant 310 may be formed of a same or similar material and formed by a same or similar method as discussed above with respect to the bottom encapsulant 125. A thinning process may be applied to expose the substrate 202 and the substrates 302. The thinning process may comprise performing a CMP process, a grinding process, an etch-back process, combinations thereof, or the like. As a result, the back side of the substrate 202, back sides of the substrates 302, and a top surface of the top encapsulant 310 may be substantially co-planar or level. The dielectric layer 316 may be formed of a same or similar material and formed by a same or similar method as discussed above with respect to the bonding layer 126. The dielectric layer 316 may act as a bonding layer in subsequent processes.

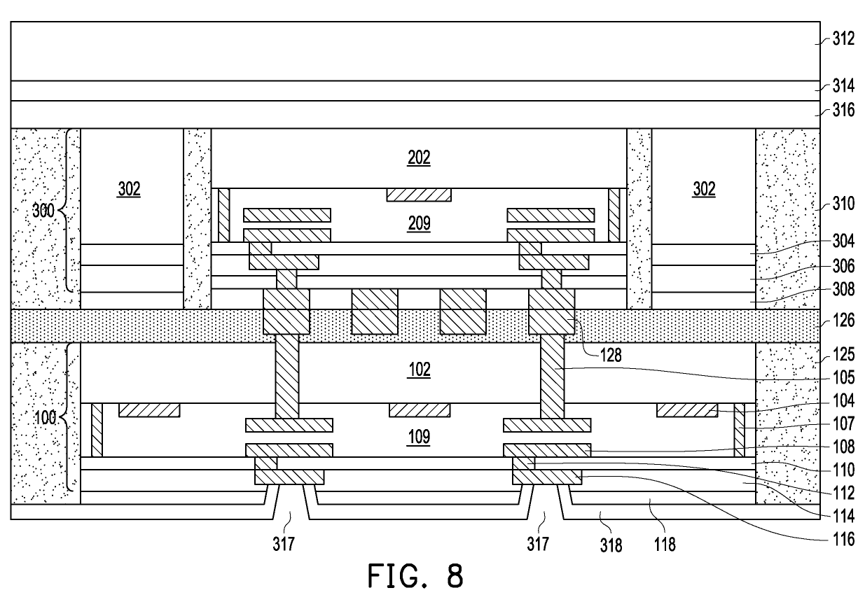

In FIG. 7, the structure over the first carrier 119 (shown in FIG. 6) is bonded to a second carrier 312, and the first carrier 119 and the bonding layer 120 are removed. The second carrier 312 may be a semiconductor carrier, a glass carrier, a ceramic carrier, or the like. The second carrier 312 may be a wafer having a same or similar size as the first carrier 119. One or more bonding layers may be disposed on the second carrier 312. In some embodiments, a bonding layer 314 is disposed on the second carrier 312. The bonding layer 314 may be formed of a same or similar material and formed by a same or similar method as discussed above with respect to the bonding layer 126. The structure over the first carrier 119 may be bonded to the second carrier 312 by bonding the dielectric layer 316 and the bonding layer 314 by a same or similar process as used for bonding the bonding layer 126 and the bonding layer 222. The first carrier 119 and the bonding layer 120 may be removed by a thinning process. The thinning process may be a CMP process, a grinding process, an etch-back process, combinations thereof, or the like. After the thinning process, bottom surfaces of the dielectric layer 118 and the bottom encapsulant 125 may be substantially co-planar or level.

In FIG. 8, openings 317 are formed through the dielectric layer 118 and the dielectric layer 114 to expose the contact pads 116, and a protective layer 318 is formed on the bottom surfaces of the dielectric layer 118 and the bottom encapsulant 125. The openings 317 may be formed by a same or similar method with respect to the openings in which the bonding pads 128 are formed. The openings 317 may expose the contact pads 116 as well as sidewalls of the dielectric layer 118 and the dielectric layer 114. The protective layer 318 may be formed of an insulating material, such as polyimide or the like, and by a coating method, such as spin-coating or the like. The protective layer 318 may cover the exposed portions of contact pads 116 and sidewalls of the dielectric layer 118 and the dielectric layer 114, as well as the bottom surfaces of the dielectric layer 118 and the bottom encapsulant 125. Then portions of the protective layer 318 that cover the exposed portions of contact pads 116 may be removed to re-expose contact pads 116.

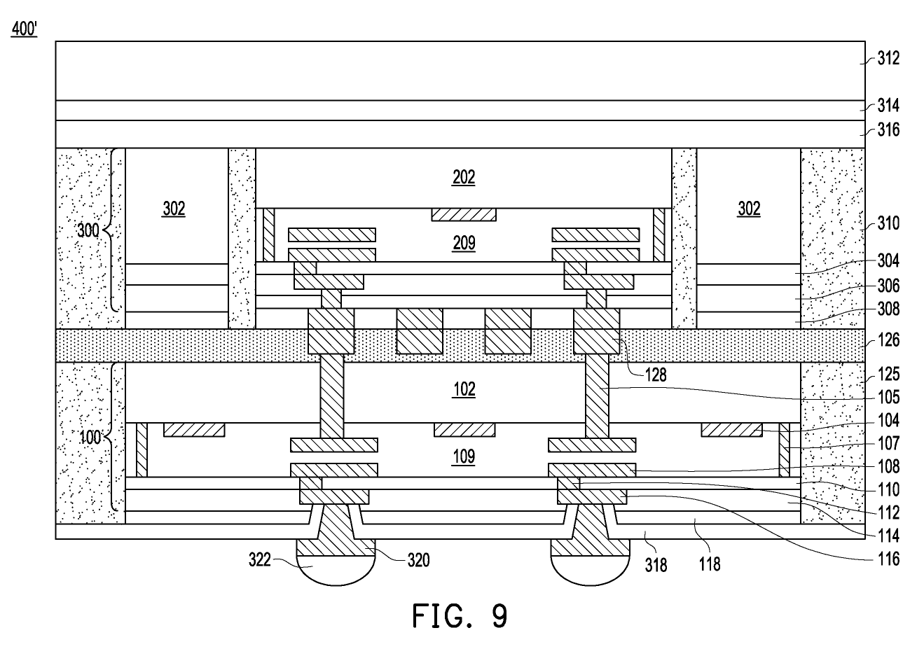

In FIG. 9, under-bump metallizations (UBMs) 320 are formed in the openings 317 (shown in FIG. 8) and electrical connectors 322 are formed on the UBMs 320. The UBMs 320 have bump portions on and extending along a surface of the protective layer 318, and have via portions extending through the openings 317 to connect to the contact pads 116. As a result, the UBMs 320 are electrically connected to the bottom semiconductor die 100. As an example to form the UBMs 320, a seed layer may be formed on the protective layer 318 and on the exposed portions of the contact pads 116. The seed layer may be a metal layer, which may be a single layer or a composite layer comprising a plurality of sub-layers formed of different materials formed using a deposition process, such as PVD or the like. A photoresist may be then formed and patterned on the seed layer. The pattern of the photoresist may have openings through the photoresist to expose the seed layer and may correspond to the UBMs 320. A conductive material may be formed in the openings of the photoresist and on the exposed portions of the seed layer by plating, such as electroless plating, electroplating, or the like. The conductive material may comprise a metal or a metal alloy, such as copper, titanium, tungsten, aluminum, the like, or combinations thereof. Then, the photoresist and portions of the seed layer on which the conductive material is not formed may be removed by an acceptable ashing or stripping process, such as using an oxygen plasma or the like. Once the photoresist is removed, exposed portions of the seed layer may be are removed, by using an acceptable etching process, such as by wet or dry etching. The remaining portions of the seed layer and conductive material may be collectively referred to as the UBMs 320.

Electrical connectors 322 are formed on the UBMs 320. The UBMs 320 and the electrical connectors 322 may be used to provide input/output connections to external electrical components, such as, other device dies, redistribution structures, printed circuit boards (PCBs), motherboards, or the like. The electrical connectors 322 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The electrical connectors 322 may include a conductive material such as solder, copper, aluminum, gold, nickel, silver, palladium, tin, the like, or a combination thereof. In some embodiments, the electrical connectors 322 are formed by initially forming a layer of solder through evaporation, electroplating, printing, solder transfer, ball placement, or the like and reflowing the layer of solder to shape the material into the desired bump shapes. In some embodiments, the electrical connectors 322 comprise metal pillars (such as a copper pillar) formed by a sputtering, printing, electro plating, electroless plating, CVD, or the like. The structure shown in FIG. 9 may be referred to as a wafer structure 400’.

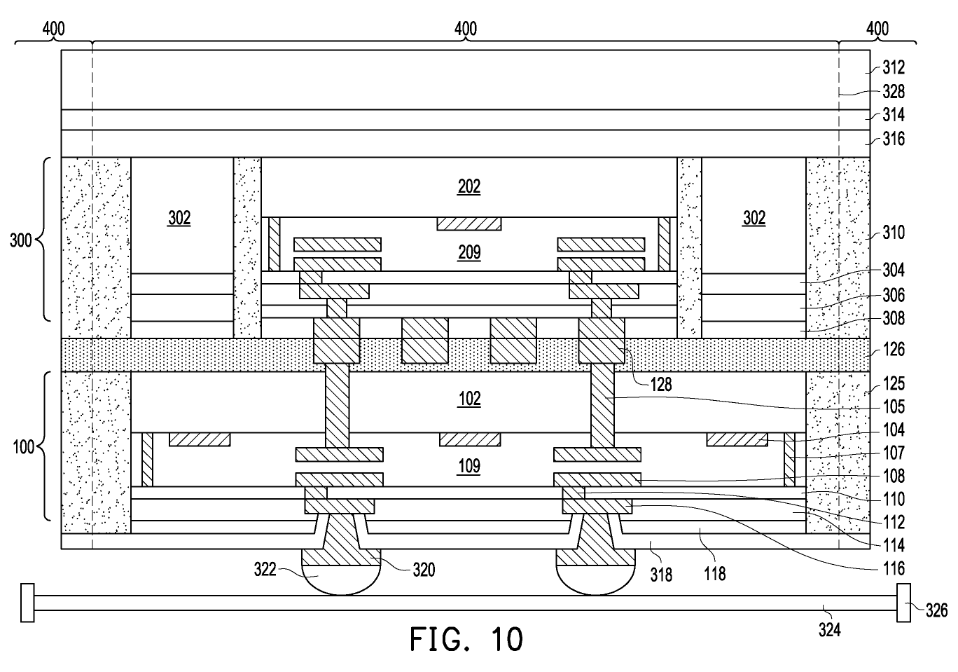

In FIG. 10, the wafer structure 400’ is singulated into discrete semiconductor packages 400. The wafer structure 400’ may be placed on a tape 324 supported by a frame 326. The wafer structure 400’ may be then singulated along scribe lines 328, so that the wafer structure 400’ is separated into discrete semiconductor packages 400. The singulation process may include a sawing process, a laser cutting process, or the like. A cleaning process or rinsing process may be performed after the singulation process. Each semiconductor package 400 may be then removed from the tape 324 as shown in FIG. 11.

The manufacturing processes discussed above correspond to a front-to-back package configuration as an example. In the front-to-back package configuration, the top semiconductor die 200 and the bottom semiconductor die 100 are oriented such that the front side of the substrate 202 of the top semiconductor die 200 faces the back side of the substrate 102 of the bottom semiconductor die 100. Other package configurations, such as front-to-front package configuration, are also contemplated. In the front-to-front package configuration, the top semiconductor die 200 and the bottom semiconductor die 100 are oriented such that the front side of the substrate 202 of the top semiconductor die 200 faces the front side of the substrate 102 of the bottom semiconductor die 100.

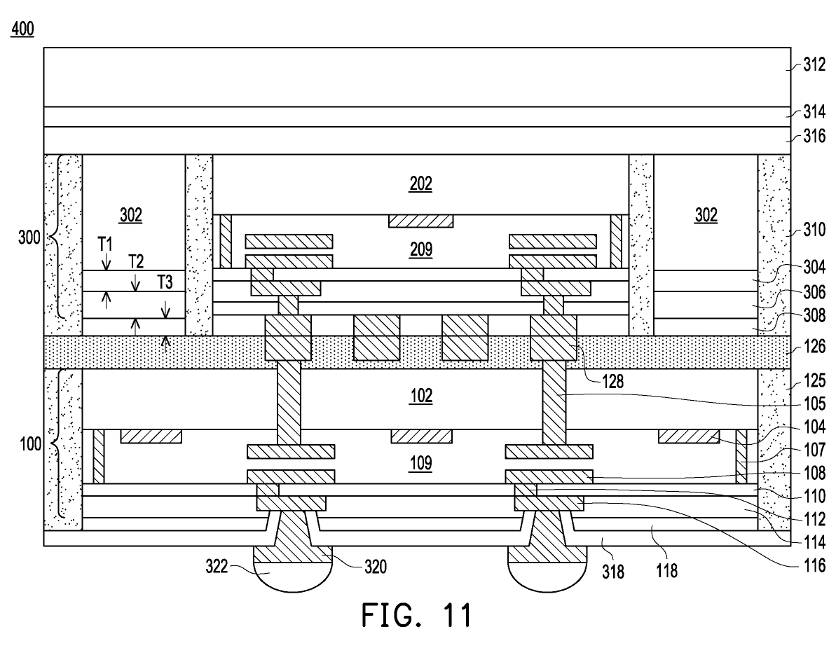

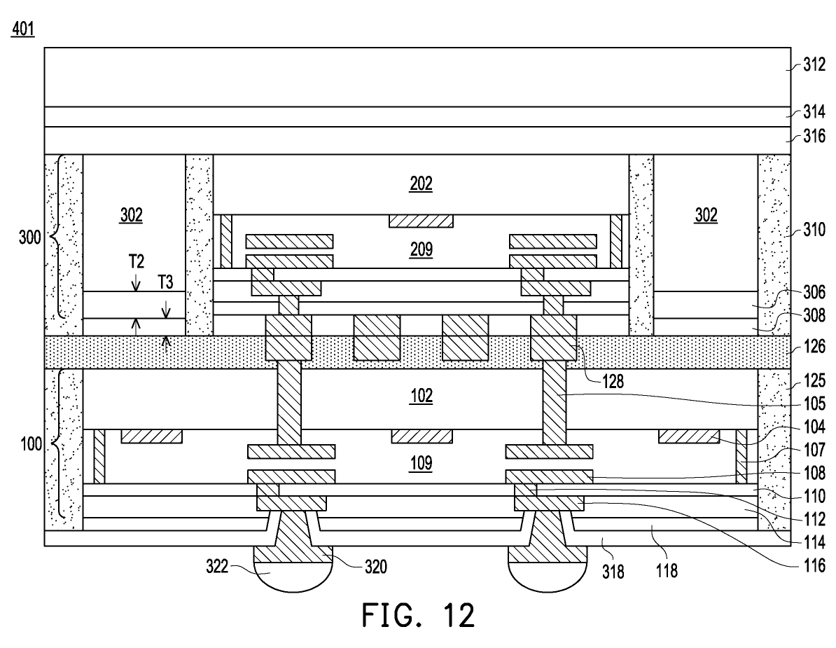

FIG. 12 shows a cross-sectional view of a semiconductor package 401 with a structure similar to the semiconductor package 400 shown in FIG. 11, wherein like reference numerals refer to like elements. FIG. 12 illustrates the embodiments where the dielectric layer 304 between the substrate 302 and the material layer 306 of each of the one or more dummy dies 300 is omitted. As a result, the material layer 306 is in contact with the substrate 302.

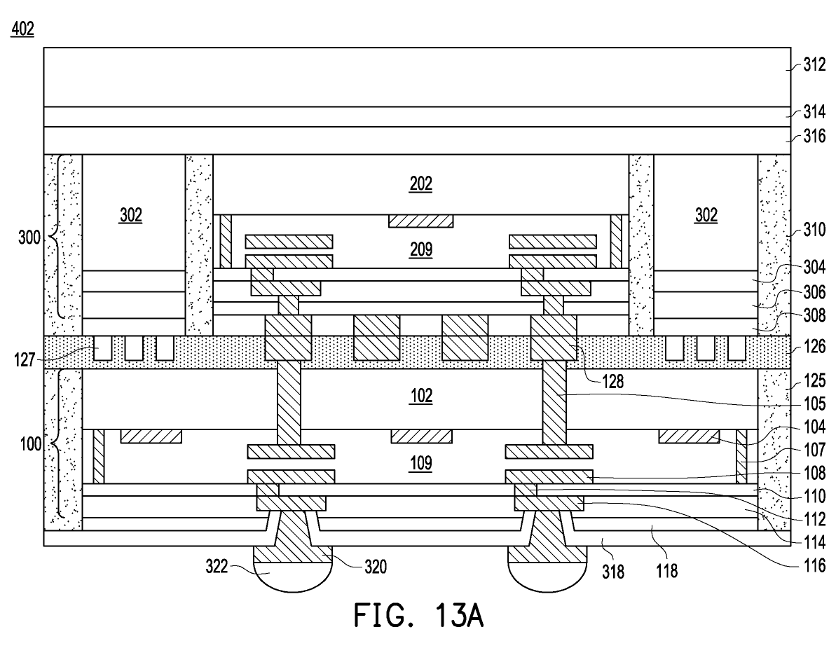

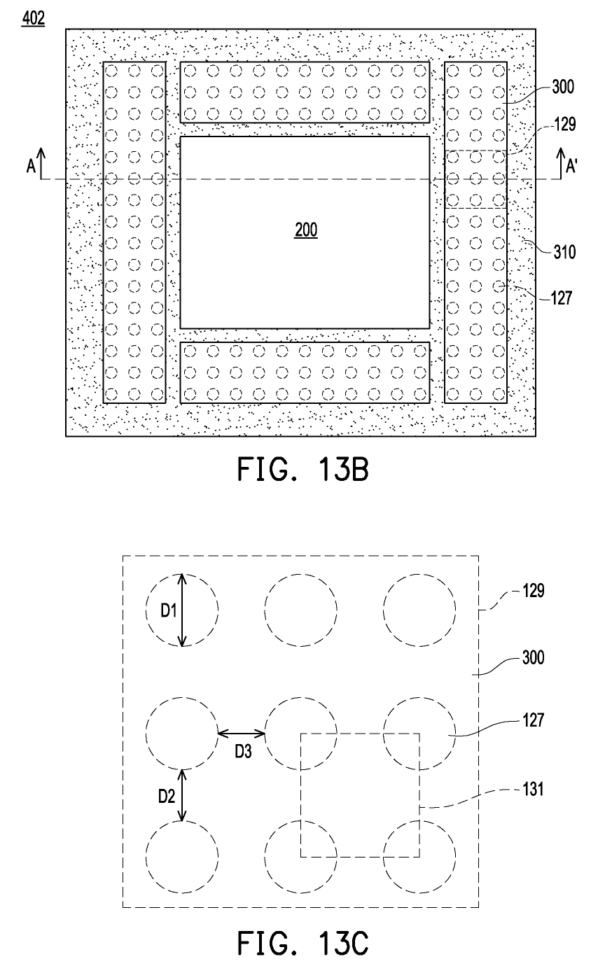

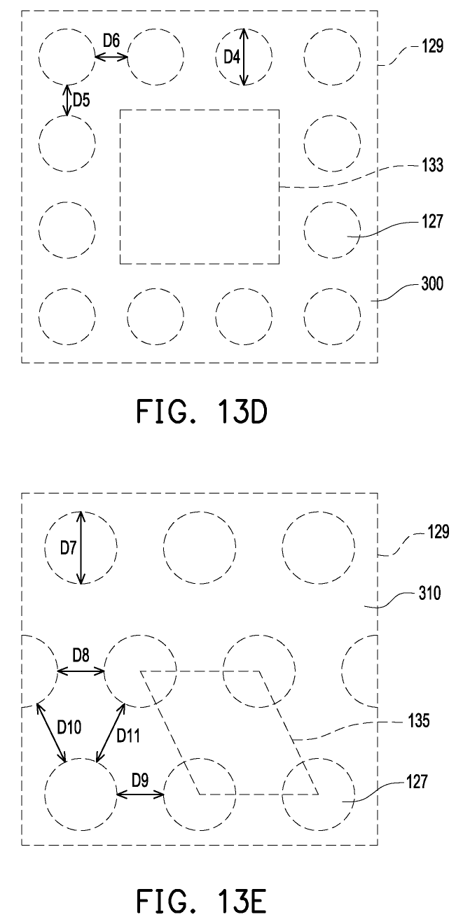

FIG. 13A shows a cross-sectional view of a semiconductor package 402 with a structure similar to the semiconductor package 400 shown in FIG. 11, wherein like reference numerals refer to like elements. FIG. 13A illustrates the embodiments wherein dummy pads are disposed in the bonding layer 126. The dummy pads 127 may have a higher thermal conductivity than the bonding layer 126, thereby improving the heat transfer from the electrical devices 104 of the bottom semiconductor die 100 to the one or more dummy dies 300. The dummy pads 127 may be embedded in the bonding layer 126, wherein top surfaces of the dummy pads 127 may be in contact with the dielectric layer 308, and sidewalls as well as bottom surfaces of the dummy pads 127 may be in contact with the bonding layer 126. The dummy pads 127 may be electrically isolated from the circuitry of the semiconductor package 400. The dummy pads 127 may be metal pads and formed of a same or similar material and by a same or similar method as the bonding pads 128. In some embodiments, the dummy pads 127 and the bonding pads 128 are formed at the same time. In some embodiments, the dummy pads 127 are formed before or after forming the bonding pads 128.

FIG. 13B shows a top-down view of the semiconductor package 402 shown in FIG. 13A, in accordance with some embodiments. The cross-sectional view shown in FIG. 13A may be obtained from the reference cross-section A-A’ in the top-down view shown in FIG. 13B, wherein like reference numerals refer to like features. The second carrier 312, the bonding layer 314, and the dielectric layer 316 are omitted, and the dummy pads 127 that are covered by the one or more dummy dies 300 are shown in dashed lines for illustrative purposes.

FIG. 13C shows a region 129 of the top-down view of the semiconductor package 402 shown in FIG. 13B, in accordance with some embodiments. In the region 129, which may be representative of the entire region with the dummy pads 127, the dummy pads 127 may be arranged in an array with various columns and rows. The number of columns and rows are shown for illustrative purposes, and some embodiments may have more or fewer columns and/or rows. The dummy pads 127 may have a circular shape with a diameter D1 in a range from about 1 µm to about 10 µm, such as about 3.5 µm. A distance D2 between two neighboring dummy pads 127 in a same column may be in a range from about 1 µm to about 100 µm, such as about 5.5 µm. A distance D3 between two neighboring dummy pads 127 in a same row may be in a range from about 1 µm to about 100 µm, such as about 5.5 µm. In some embodiments, the distance D2 is the same as the distance D3. In some embodiments, the distance D2 is different from the distance D3. A density of the dummy pads 127 may be greater than about 10%, such as about 11.9%. The density of the dummy pads 127 may be a ratio of a total area of the dummy pads 127 with in a region 131 to a total area of the region 131. The region 131 may be a rectangle and may be formed by connecting center points of two neighboring dummy pads 127 in a first row and two neighboring dummy pads 127 in an second row adjacent the first row, wherein the two neighboring dummy pads 127 in the second row are the closest to the two neighboring dummy pads 127 in the first row.

FIG. 13D shows a region 129 of the top-down view of the semiconductor package 402 shown in FIG. 13B, in accordance with some embodiments. In the region 129, which may be representative of the entire region with the dummy pads 127, the dummy pads 127 may be arranged in an array with columns and rows similar to the arrangement described with respect to FIG. 13C. The dummy pads 127 may be selectively formed over the thermal hotspots created by underlying the electrical devices 104. As a result, some regions, such as region 133, within the array may be free of the dummy pads 127. The dummy pads 127 may have a circular shape with a diameter D4 in a range from about 1 µm to about 10 µm, such as about 3.5 µm. A distance D5 between two neighboring dummy pads 127 in a same column may be in a range from about 1 µm to about 100 µm, such as about 5.5 µm. A distance D6 between two neighboring dummy pads 127 in a same row may be in a range from about 1 µm to about 100 µm, such as about 5.5 µm. In some embodiments, the distance D5 is the same as the distance D6. In some embodiments, the distance D5 is different from the distance D6.

FIG. 13E shows a region 129 of the top-down view of the semiconductor package 402 shown in FIG. 13B, in accordance with some embodiments. In the region 129, which may be representative of the entire region with the dummy pads 127, the dummy pads 127 may be arranged in a staggered array with various rows. The dummy pads 127 may have a circular shape with a diameter D7 in a range from about 1 µm to about 10 µm, such as about 3.5 µm. A distance D8 between two neighboring dummy pads 127 in a first row may be in a range from about 1 µm to about 100 µm, such as about 5.5 µm. A distance D9 between two neighboring dummy pads 127 in a second row adjacent the first row may be in a range from about 1 µm to about 100 µm, such as about 5.5 µm. A distance D10 between two neighboring dummy pads 127 in two adjacent rows along a first direction may be in a range from about 1 µm to about 100 µm, such as about 5.5 µm. A distance D11 between two neighboring dummy pads 127 in two adjacent rows along a second direction may be in a range from about 1 µm to about 100 µm, such as about 5.5 µm. In some embodiments, the distance D8 is the same as the distance D9, the distance D10 is the same as the distance D11, and the distance D8 is different from the distance D10. In some embodiments, the distance D8 is the same as the distance D9, the distance D10, and the distance D11. A density of the dummy pads 127 may be greater than about 10%, such as about 11.9%. The density of the dummy pads 127 may be a ratio of a total area of the dummy pads 127 with in a region 135 to a total area of the region 135. The region 135 may be a parallelogram and may be formed by connecting center points of two neighboring dummy pads 127 in the first row and two neighboring dummy pads 127 in the second row, wherein the two neighboring dummy pads 127 in the second row are the closest to the two neighboring dummy pads 127 in the first row.

The shape, size, number, and arrangement of the dummy pads 127 shown in FIGS. 13B, 13C, 13D, 13E are provided as examples. Other shapes, sizes, numbers, and arrangements of the dummy pads 127 are also contemplated.

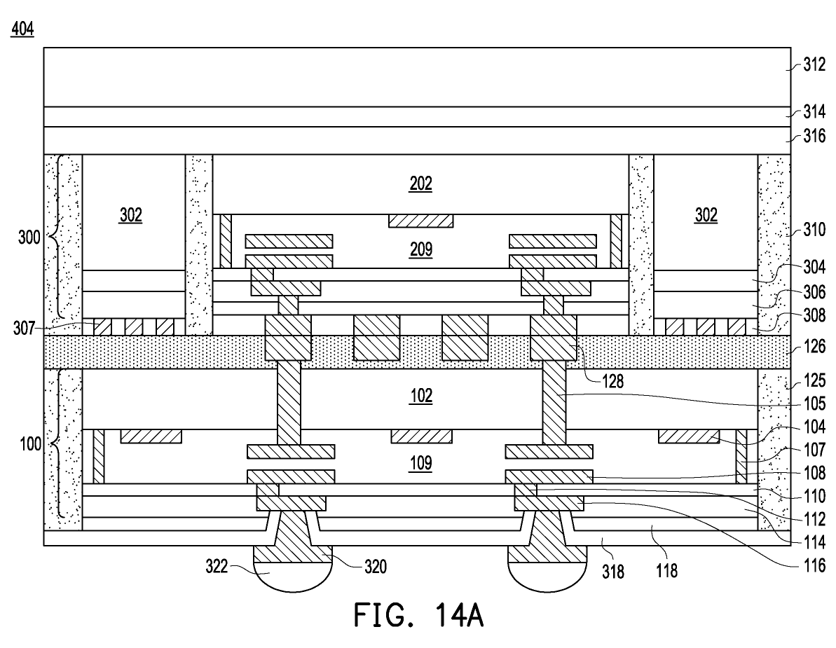

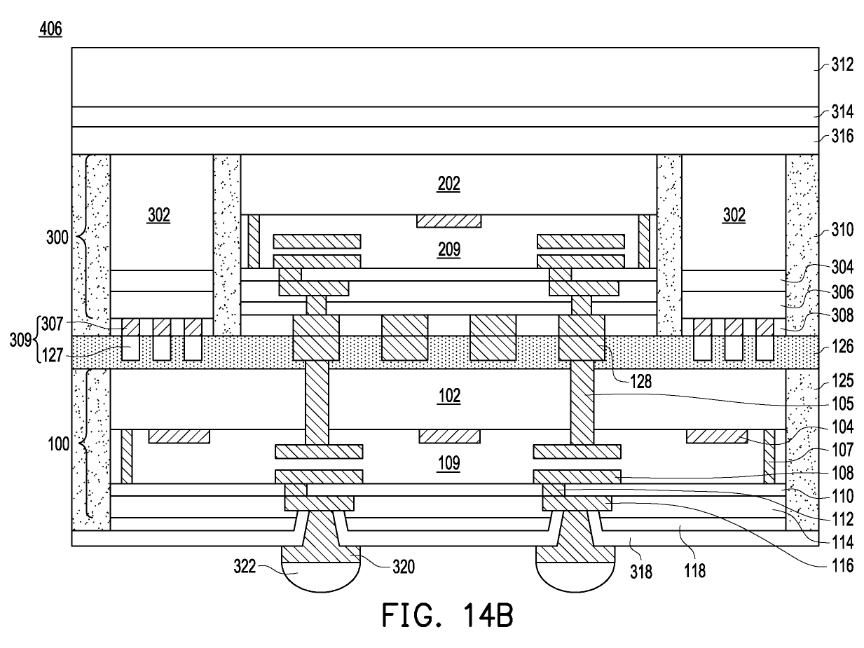

FIG. 14A shows a cross-sectional view of a semiconductor package 404 with a structure similar to the semiconductor package 400 shown in FIG. 11, wherein like reference numerals refer to like elements. FIG. 14A illustrates the embodiments where dummy pads 307 are disposed in the dielectric layer 308 of the one or more dummy dies 300. The dummy pads 307 may have a higher thermal conductivity than the dielectric layer 308, thereby improving the heat transfer from the electrical devices 104 of the bottom semiconductor die 100 to the one or more dummy dies 300. The dummy pads 307 may extend through the dielectric layer 308, wherein top surfaces of the dummy pads 307 may be in contact with the material layer 306 and bottom surfaces of the dummy pads 307 may be in contact with the bonding layer 126. The dummy pads 307 may be electrically isolated from the circuitry of the semiconductor package 400. The dummy pads 307 may be metal pads and formed of a same or similar material and by a same or similar method as the bonding pads 224. In some embodiments, the shapes, sizes, numbers, and arrangements of the dummy pads 307 are substantially the same as the shapes, sizes, numbers, and arrangements of the dummy pads 127 described with respect to FIGS. 13B, 13C, 13D, and 13E in the top-down view. Other shapes, sizes, numbers, and arrangements of the dummy pads 307 are also contemplated. In some embodiments, the dummy pads 307 are omitted in some portions of the one or more dummy dies 300.

FIG. 14B shows a cross-sectional view of a semiconductor package 406 with a structure similar to the semiconductor package 402 shown in FIG. 13A and the semiconductor package 404 shown in FIG. 14A, wherein like reference numerals refer to like elements. FIG. 14B illustrates the embodiments where dummy pads 127 are disposed in the bonding layer 126 and dummy pads 307 are disposed in the dielectric layer 308 of the one or more dummy dies 300. Each dummy pad 127 may be bonded to a corresponding dummy pad 307. The dummy pads 127 may have a higher thermal conductivity than the bonding layer 126 and the dummy pads 307 may have a higher thermal conductivity than the dielectric layer 308, thereby improving the heat transfer from the electrical devices 104 of the bottom semiconductor die 100 to the one or more dummy dies 300. The dummy pads 127 may be embedded in the bonding layer 126, wherein top surfaces of the dummy pads 127 may be in contact with the dummy pads 307, and sidewalls as well as bottom surfaces of the dummy pads 127 may be in contact with the bonding layer 126. The dummy pads 307 may extend through the dielectric layer 308, wherein top surfaces of the dummy pads 307 may be in contact with the material layer 306 and bottom surfaces of the dummy pads 307 may be in contact with the dummy pads 127. The dummy pads 127 and the dummy pads 307 may be bonded by metal-to-metal bonding and the bonding layer 126 and the dielectric layer 308 may be bonded by dielectric-to-dielectric bonding. Each dummy pad 127 and the corresponding dummy pad 307 may be collectively referred to as a dummy feature 309 after bonding. The dummy features 309 may be electrically isolated from the circuitry of the semiconductor package 400. In some embodiments, the shapes, sizes, numbers, and arrangements of the dummy features 309 are substantially the same as the shapes, sizes, numbers, and arrangements of the dummy pads 127 described with respect to FIGS. 13B, 13C, 13D, and 13E in the top-down view. Other shapes, sizes, numbers, and arrangements of the dummy features 309 are also contemplated. In some embodiments, the dummy pads 307 are omitted in some portions of the one or more dummy dies 300.

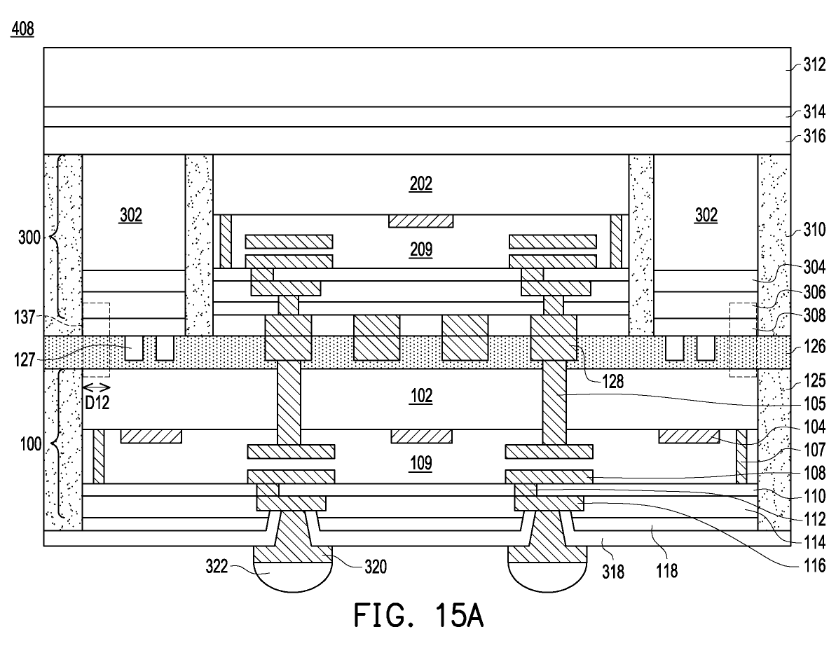

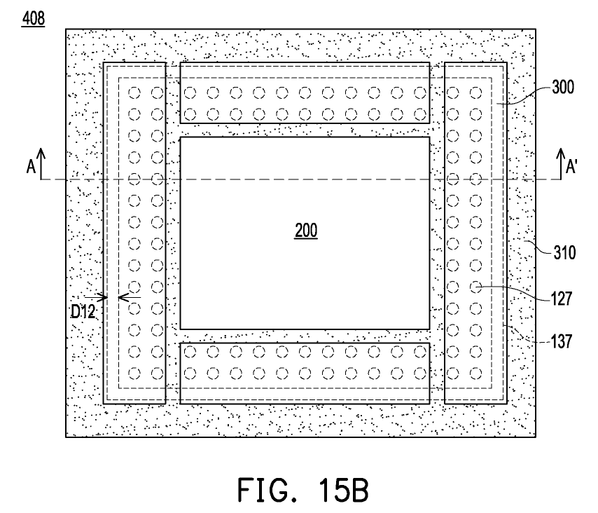

FIGS. 15A and 15B show a cross-sectional view and a top-down view, respectively, of a semiconductor package 408 with a structure similar to the semiconductor package 402 shown in FIGS. 13A and 13B, wherein like reference numerals refer to like elements. The cross-sectional view shown in FIG. 15A may be obtained from the reference cross-section A-A’ in the top-down view shown in FIG. 15B, wherein like reference numerals refer to like features. The second carrier 312, the bonding layer 314, and the dielectric layer 316 are omitted, and the dummy pads 127 that are covered by the one or more dummy dies 300 are shown in dashed lines for illustrative purposes. FIGS. 15A and 15B illustrate the embodiments where a keep-out zone (KOZ) 137 is disposed in the bonding layer 126 over the seal ring 107 of the bottom semiconductor die 100, wherein the KOZ 137 may be free of the dummy pads 127. A mismatch between a coefficient of thermal expansion (CTE) of the seal ring 107 and a CTE of the one or more dielectric layers 109 may induce stress in the portions of the bonding layer 126 in the KOZ 137, which may increase the risk of delamination of the one or more dummy dies 300 bonded to the bonding layer 126. Omitting the dummy pads 127 in the KOZ 137 may improve the bonding strength between the one or more dummy dies 300 and the bonding layer 126, thereby mitigating the risk of delamination of the one or more dummy dies 300. The KOZ 137 has a width D12 which may be in a range from about 10 µm to about 50 µm, such as about 20 µm.

In some embodiments, the KOZ 137 applies to the semiconductor package 404, wherein the KOZ 137 is disposed in the dielectric layers 308 of the one or more dummy dies 300 over the seal ring 107 and the KOZ 137 is free of the dummy pads 307. In some embodiments, the KOZ 137 applies to the semiconductor package 406, wherein the KOZ 137 is disposed in the dielectric layers 308 of the one or more dummy dies 300 and the bonding layer 126 over the seal ring 107 and the KOZ 137 is free of the dummy features 309.

The embodiments of the present disclosure have some advantageous features. By utilizing the material layers 306 and the dummy pads 307 in the one or more dummy dies 300, and the dummy pads 127 in the bonding layer 126 to which the one or more dummy dies 300 are bonded, the heat generated by electrical devices 104 in the bottom semiconductor die 100 during operation may be transferred away from the semiconductor packages 400, 401, 402, 404, and 408, which may lead to higher efficiency and better long-term reliability of the semiconductor packages 400, 401, 402, 404, and 408.

In an embodiment, a semiconductor package includes a first semiconductor die; a first bonding layer on the first semiconductor die; a second semiconductor die bonded to the first bonding layer; and a first dummy die bonded to the first bonding layer, the first dummy die including: a substrate; a material layer on the substrate, wherein the material layer is between the substrate and the first bonding layer, and wherein the material layer includes a first material with a first thermal conductivity; and a second bonding layer on the material layer, wherein the second bonding layer is between the material layer and the first bonding layer, and wherein the second bonding layer includes a second material with a second thermal conductivity different from the first thermal conductivity. In an embodiment, the first thermal conductivity is larger than the second thermal conductivity. In an embodiment, the first material has a first Young’s modulus and the second material has a second Young’s modulus, and wherein the first Young’s modulus is larger than the second Young’s modulus. In an embodiment, the first dummy die further includes an adhesion layer on the substrate, wherein the adhesion layer is between the substrate and the first bonding layer, and wherein the adhesion layer includes a third material different from the first material. In an embodiment, the first bonding layer is bonded to the second bonding layer by dielectric-to-dielectric bonding. In an embodiment, the semiconductor package further includes dummy pads in the first bonding layer, wherein the dummy pads include metal, and wherein the dummy pads are in contact with the second bonding layer. In an embodiment, the semiconductor package further includes dummy pads in the second bonding layer, wherein the dummy pads include metal, and wherein the dummy pads are in contact with the first bonding layer. In an embodiment, the semiconductor package further includes first dummy pads in the first bonding layer; and second dummy pads in the second bonding layer, and wherein each of the first dummy pads is bonded to a corresponding one of the second dummy pads by metal-to-metal bonding.

In an embodiment, a semiconductor package includes a first semiconductor die; a first encapsulant encircling the first semiconductor die in a top-down view; a bonding layer on the first semiconductor die and the first encapsulant; a first plurality of dummy pads in the bonding layer; a second semiconductor die bonded to the bonding layer, the bonding layer being between the first semiconductor die and the second semiconductor die; a first dummy die bonded to the bonding layer, wherein the first dummy die covers the first plurality of dummy pads, the first dummy die including: a substrate, wherein a first side of the substrate faces the bonding layer; a first dielectric layer on the first side of the substrate; and a second dielectric layer, wherein the second dielectric layer is bonded to the bonding layer; and a second encapsulant encircling the second semiconductor die and the first dummy die in the top-down view. In an embodiment, the second semiconductor die is electrically coupled to the first semiconductor die, and wherein the first dummy die is electrically isolated from the first semiconductor die. In an embodiment, the first dummy die further includes a material layer between the first dielectric layer and the second dielectric layer, and wherein the material layer is more thermally conductive than the first dielectric layer and the second dielectric layer. In an embodiment, the first plurality of dummy pads form an array pattern in the top-down view. In an embodiment, the first plurality of dummy pads form a staggered array pattern in the top-down view. In an embodiment, the first dummy die further includes a second plurality of dummy pads extending through the second dielectric layer, wherein the second plurality of dummy pads are in contact with corresponding ones of the first plurality of dummy pads, and wherein the first dummy die is bonded to the bonding layer and the first plurality of dummy pads by dielectric-to-dielectric bonding and metal-to-metal bonding, respectively.

In an embodiment, a method of manufacturing a semiconductor package includes forming a first dielectric layer on a first semiconductor die, wherein the first dielectric layer includes a first material; forming first metal pads in the first dielectric layer; bonding a second semiconductor die to the first dielectric layer and the first metal pads using dielectric-to-dielectric bonding and metal-to-metal bonding; and bonding one or more dummy dies to the first dielectric layer, and wherein each of the one or more dummy dies includes: a substrate; a second dielectric layer bonded to the first dielectric layer, wherein the second dielectric layer includes a second material; and a material layer between the substrate and the second dielectric layer, wherein the material layer includes a third material different from the second material, and wherein the third material has a larger thermal conductivity than the second material. In an embodiment, the method further includes forming second metal pads in the first dielectric layer; and bringing the second dielectric layer of each of the one or more dummy dies into contact with the first dielectric layer and the second metal pads, wherein the one or more of dummy dies are bonded to the first dielectric layer using dielectric-to-dielectric bonding. In an embodiment, the first semiconductor die includes one or more electrical devices and a seal ring encircling the one or more electrical devices in a top down view, wherein a keep-out zone in the first dielectric layer is disposed directly over the seal ring, and wherein the keep-out zone is free of the second metal pads. In an embodiment, the method further includes forming second metal pads in the first dielectric layer; bringing the second dielectric layer of each of the one or more dummy dies into contact with first dielectric layer; and bringing third metal pads of each of the one or more dummy dies into contact with a corresponding second metal pad of the second metal pads, wherein the third metal pads extend through the second dielectric layer of each of the one or more of dummy dies, and wherein the one or more dummy dies are bonded to the first dielectric layer and the second metal pads using dielectric-to-dielectric bonding and metal-to-metal bonding. In an embodiment, the first semiconductor die includes one or more electrical devices and a seal ring encircling the one or more electrical devices in a top down view, wherein a first keep-out zone in the first dielectric layer is disposed directly over the seal ring, wherein the first keep-out zone is free of the second metal pads, wherein a second keep-out zone in each of the one or more dummy dies is disposed directly over the seal ring, and wherein the second keep-out zone is free of the third metal pads. In an embodiment, the method further includes forming a first encapsulant encircling the first semiconductor die in a top-down view; and forming a second encapsulant encircling the second semiconductor die and the one or more dummy dies in the top-down view, wherein the first dielectric layer is between the first encapsulant and the second encapsulant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor package, the method comprising:
forming a first dielectric layer on a first semiconductor die;
forming first metal pads in the first dielectric layer;
bonding a second semiconductor die to the first dielectric layer and the first metal pads using dielectric-to-dielectric bonding and metal-to-metal bonding; and
bonding one or more dummy dies to the first dielectric layer, wherein each of the one or more dummy dies is electrically isolated from the first semiconductor die, and wherein each of the one or more dummy dies comprises:
a substrate;
a second dielectric layer bonded to the first dielectric layer, wherein the second dielectric layer comprises a second material; and
a material layer between the substrate and the second dielectric layer, wherein the material layer comprises a third material different from the second material, and wherein the third material has a higher thermal conductivity than the second material.

2. The method of claim 1, further comprising:
forming second metal pads in the first dielectric layer; and
bringing the second dielectric layer of each of the one or more dummy dies into contact with the first dielectric layer and the second metal pads, wherein the one or more dummy dies are bonded to the first dielectric layer using dielectric-to-dielectric bonding.

3. The method of claim 2, wherein the first semiconductor die comprises one or more electrical devices and a seal ring encircling the one or more electrical devices in a top down view, wherein a keep-out zone in the first dielectric layer is disposed directly over the seal ring, and wherein the keep-out zone is free of the second metal pads.

4. The method of claim 1, further comprising:
forming second metal pads in the first dielectric layer;
bringing the second dielectric layer of each of the one or more dummy dies into contact with the first dielectric layer; and
bringing third metal pads of each of the one or more dummy dies into contact with a corresponding second metal pad of the second metal pads, wherein the third metal pads extend through the second dielectric layer of each of the one or more dummy dies, and wherein the one or more dummy dies are bonded to the first dielectric layer and the second metal pads using dielectric-to-dielectric bonding and metal-to-metal bonding.

5. The method of claim 4, wherein the first semiconductor die comprises one or more electrical devices and a seal ring encircling the one or more electrical devices in a top down view, wherein a first keep-out zone in the first dielectric layer is disposed directly over the seal ring, the first keep-out zone being free of the second metal pads, and wherein a second keep-out zone in each of the one or more dummy dies is disposed in the second dielectric layer, directly over the seal ring, the second keep-out zone being free of the third metal pads.

6. The method of claim 1, further comprising:
forming a first encapsulant encircling the first semiconductor die in a top-down view; and
forming a second encapsulant encircling the second semiconductor die and the one or more dummy dies in the top-down view, wherein the first dielectric layer is between the first encapsulant and the second encapsulant.

7. The method of claim 1, wherein each of the one or more dummy dies further comprises an adhesion dielectric layer between the substrate and the material layer, and wherein the adhesion dielectric layer adheres the material layer to the substrate.

8. A method of manufacturing a semiconductor package, the method comprising:
forming a first dielectric layer on a first semiconductor die; and
bonding a first dummy die to the first dielectric layer, wherein the first dummy die is electrically isolated from the first semiconductor die, and wherein the first dummy die comprises:
a substrate;
an adhesion dielectric layer on the substrate;
a material layer on the adhesion dielectric layer, wherein the adhesion dielectric layer is between the substrate and the material layer, wherein the material layer has a thermal conductivity higher than the adhesion dielectric layer; and
a second dielectric layer on the material layer, wherein the material layer has a thermal conductivity higher than the second dielectric layer, and wherein the second dielectric layer is bonded to the first dielectric layer.

9. The method of claim 8, wherein first dummy pads are disposed in the first dielectric layer, the first dummy pads having a higher thermal conductivity than the first dielectric layer.

10. The method of claim 9, wherein the first dummy pads are arranged in an array in a top-down view, wherein the first semiconductor die comprises one or more electrical devices, and wherein the first dummy pads are formed over thermal hotspots created by the electrical devices, such that a region within the array is free of the first dummy pads in the top-down view.

11. The method of claim 9, wherein top surfaces of the first dummy pads are in contact with the second dielectric layer, and wherein sidewalls and bottom surfaces of the first dummy pads are in contact with the first dielectric layer.

12. The method of claim 9, wherein second dummy pads are disposed in the second dielectric layer, the second dummy pads having a thermal conductivity higher than the second dielectric layer.

13. The method of claim 12, wherein each of the first dummy pads is bonded to a corresponding second dummy pad of the second dummy pads.

14. The method of claim 12, wherein the first semiconductor die comprises a seal ring, wherein a keep-out zone is disposed in the first dielectric layer and the second dielectric layer, the keep-out zone being located directly over the seal ring, and wherein the keep-out zone is free of the first dummy pads and the second dummy pads.

15. The method of claim 8, wherein the second dielectric layer comprises dummy pads, wherein the dummy pads have a thermal conductivity higher than the second dielectric layer, and wherein the dummy pads extend through the second dielectric layer, top surfaces of the dummy pads being in contact with the material layer and bottom surfaces of the dummy pads being in contact with the first dielectric layer.

16. A method of manufacturing a semiconductor package, the method comprising:
forming a first dielectric layer on a first semiconductor die;
bonding a second semiconductor die to the first dielectric layer, such that the second semiconductor die is electrically coupled to the first semiconductor die; and bonding one or more dummy dies to the first dielectric layer, wherein the one or more dummy dies collectively encircle the second semiconductor die in a top-down view, wherein each of the one or more dummy dies is electrically isolated from the first semiconductor die, and wherein each of the one or more dummy dies comprises:
a substrate;
an adhesion dielectric layer on the substrate;
a material layer on a side of the adhesion dielectric layer opposite the substrate; and
a second dielectric layer on a side of the material layer opposite the adhesion dielectric layer, wherein the material layer has a thermal conductivity higher than the second dielectric layer and the adhesion dielectric layer, and wherein the second dielectric layer is bonded to the first dielectric layer.

17. The method of claim 16, wherein the material layer has a Young's Modulus higher than the adhesion dielectric layer and the second dielectric layer.

18. The method of claim 17, wherein the material layer has a larger thickness than the adhesion dielectric layer and the second dielectric layer.

19. The method of claim 17, wherein the substrate has a thermal conductivity higher than the adhesion dielectric layer and the second dielectric layer.

20. The method of claim 17, further comprising, after bonding the one or more dummy dies to the first dielectric layer:
forming an encapsulant over a remaining portion of the first dielectric layer, such that the encapsulant extends along sidewalls of the second semiconductor die and the one or more dummy dies, and encircles the second semiconductor die and the one or more dummy dies in the top-down view.
